(19) United States
(12) Patent Application Publication
(10) Pub. No.: US 2005/0244756 A1
(43) Pub. Date: Nov. 3, 2005

(54) Etch rate control

(76) Inventor: Mark A. Clarner, Concord, NH (US)

Correspondence Address: FISH & RICHARDSON PC, P.O. BOX 1022, MINNEAPOLIS, MN, 55440-1022, US

(21) Appl. No.: 10/837,090

(22) Filed: Apr. 30, 2004

(51) Int. Cl. G03F 7/00

(52) U.S. Cl. 430/320; 430/323

(57) ABSTRACT

A method of forming a cavity in the side of a substrate (e.g., a mold plate adapted to be assembled with one or more additional plates to define a mold for a hook or a stem on a hook component of a touch fastener) includes forming on the substrate a layer of photoresist material on the substrate having a pattern of etchant-passing and etchant-blocking regions and applying a chemical etchant to the substrate such that the etchant undercuts the etchant-blocking regions to form a single contiguous cavity on the plate in an area beneath said pattern of etchant-passing and etchant-blocking regions.

### TECHNICAL FIELD

This invention relates to photochemical etching to form cavities on a substrate.

### BACKGROUND

Photochemical etching commonly involves placing a mask over an etchable substrate that has been coated with a layer of photoresist material and then exposing the photoresist material. If negative photoresist is used, the exposed areas of the photoresist become cured and resistant to chemical etchant. Areas of the photoresist that are not exposed are washed away using a solvent leaving a portion of the underlying substrate uncovered and ready for etching. If positive photoresist is used, then exposed areas are weakened and are easily washed away.

Once the photoresist mask has been applied, chemical etchant is applied to the substrate to create a cavity in the uncovered areas of the substrate. Often applications, such as the creation of microhook molds for hook fasteners, seek to create very small molds that have complex shapes. U.S. Pat. No. 5,900,350 describes a method for creating microhook molds for hook fasteners and is fully incorporated herein by reference.

### SUMMARY

In one aspect, the invention features a method of forming a cavity on a substrate (e.g., a microhook mold plate, semiconductor die, optical lens plate, etc.) that includes forming on the substrate a layer of photoresist material that includes a pattern of etchant-passing and etchant-blocking regions. Chemical etchant is applied to the substrate such that etchant passed through the etchant-passing regions undercuts the etchant-blocking regions to form a single contiguous cavity on the substrate in the area beneath the pattern of etchant-passing and etchant-blocking regions.

In some configurations, forming the patterned layer of photoresist material on the first mold plate includes applying photoresist material to at least one side of the substrate, placing over the photoresist material a mask having a shaded region adapted to partially block exposure of photoresist material disposed beneath the shaded region, and exposing the photoresist material to light through the mask. If negative photoresist material is used, the unexposed areas are removed to create the layer of photoresist material having a pattern of etchant-passing and etchant-blocking regions. If positive photoresist material is used, exposed areas are removed to create the patterned layer. The etchant-passing regions of the photoresist in some configurations may include apertures bounded by etchant-blocking regions, and the etchant-blocking regions may include discrete, bounded areas of photoresist material surrounded by etchant-passing regions void of photoresist material. The pattern of the etchant-passing and etchant-blocking regions may be uniform to form a cavity having a substantially uniform depth or may be non-uniform to form a cavity having a variable depth. In some configurations the pattern of etchant-passing and etchant-blocking regions may be selected to form a cavity that extends completely through the substrate when etchant is applied.

In some configurations, the substrate may be a mold plate adapted to be assembled with one or more additional plates to define a mold for a hook or stem on a hook component of a touch fastener.

In another aspect, the invention features a method of forming a cavity on a substrate that includes applying a photoresist material to the substrate, placing over the photoresist material a mask that has a shaded region adapted to partially block exposure of photoresist material disposed beneath the shaded region, exposing the photoresist material to light through the mask, and applying a chemical etchant to the plate such that a single contiguous cavity is formed on the substrate in the area corresponding to the shaded region of the mask.

In another aspect, the invention features a method of forming a sheet-form product having an array of projections extending from a broad surface that includes forming a cavity on a first mold plate by forming a layer of photoresist material that includes a pattern of etchant-passing and etchant-blocking regions on at least one side of the first mold plate. Chemical etchant is applied to the plate such that the etchant undercuts the etchant-blocking regions to form a single contiguous cavity on the plate in an area beneath the pattern of etchant-passing and etchant-blocking regions. The first mold plate is assembled with one or more additional plates to form a mold, the cavity cooperating with a surface of an adjacent plate to at least partially define one of an array of mold cavities extending inward from a surface of the mold. Resin is applied to the surface of the mold and forcing some of the resin into the mold cavities to form an array of projections extending integrally from a layer of resin formed on the mold surface.

In some configurations, the formation of the patterned layer of photoresist material on the first mold plate includes applying photoresist material to at least one side of the plate, placing over the photoresist material a mask having a shaded region adapted to partially block exposure of photoresist material disposed beneath the shaded region, and exposing the photoresist material to light through the mask. If negative photoresist material is used, the unexposed areas are removed to create the layer of photoresist material having a pattern of etchant-passing and etchant-blocking regions. If positive photoresist material is used, exposed areas are removed to create the patterned layer. The etchant-passing regions of the photoresist in some configurations may include apertures bounded by etchant-blocking regions, and the etchant-blocking regions may include discrete, bounded areas of photoresist material surrounded by etchant-passing regions void of photoresist material. The pattern of the etchant-passing and etchant-blocking regions may be uniform to form a cavity having a substantially uniform depth or may be non-uniform to form a cavity having a variable depth.

In some configurations, the cavity formed on the first mold plate is in the shape of a hook or a stem for use in a hook component of a touch fastener.

In another aspect, the invention features a method of forming a mold form for making a sheet-form product having an array of projections extending from a broad surface that includes applying a photoresist material to at least one side of a first mold plate, placing over the photoresist material a mask having a shaded region adapted to partially block exposure of the photoresist material disposed beneath the shaded region, and exposing the photoresist material to light through the mask. Chemical etchant is applied to the plate such that a single contiguous cavity is formed on the plate in the area corresponding to the shaded region of the mask. The first mold plate is assembled with one or more additional mold plates to form a mold such that the cavity cooperates with a surface of an adjacent plate to at least partially define one or an array of mold cavities extending inward from a surface of the mold.

In some configurations, the shaded region of the mask includes a pattern of light-blocking regions and light-passing regions (e.g., apertures bounded by light-blocking regions or discrete, bounded areas of mask material surrounded by light-passing regions void of mask material) printed on a non-opaque sheet (e.g., Mylar® film) using a high-resolution plotter or printer. The shaded region of the mask may include an area having a uniform exposure density such application of the chemical etchant to the plate results in a cavity having an approximately uniform depth in an area corresponding to the shaded region of the mask having a uniform exposure density. The shaded region may include an area having a non-uniform exposure density such that application of the chemical etchant to the plate results in a cavity having a variable depth in the area corresponding to the shaded region of the mask having a non-uniform exposure density. The mask may also include a second region adapted to completely block exposure of the photoresist material disposed beneath the second region.

In some configurations, the etchable plate defines a perimeter having some cross-sectional shape (e.g., circular, rectangular, etc) and the cavities are etched along the perimeter of the plate. The cavity formed in the plate may have a hook shape such as one that includes a base and a tip and a cross-sectional area that tapers from the base of the cavity to the tip. The cavity may also have hook shape that includes a pedestal portion contiguous to a crook portion and at least one barb protruding from either the pedestal portion or the crook portion. In other configurations, the cavity may have a stem shape.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagram of a side view of a hook mold.

FIGS. 2-3 are cut away views of the hook mold shown in FIG. 1.

FIGS. 4-5 are diagrams of a hook component of a touch fastener.

FIG. 6 is a diagram of a process for making molded hook members.

FIGS. 7A-7C are diagrams of a molding roll for making molded hook members.

FIG. 8 is a diagram of a mask used to create a cavity for a hook mold.

FIGS. 9A-9D are a series of diagrams illustrating a process for creating a cavity for a hook mold.

FIGS. 10A-10D are a series of diagrams illustrating a process for creating a cavity having a gradually increasing depth on a substrate.

FIGS. 11A-11C are diagrams of masks used to create cavities for hook molds.

FIGS. 12A and 13A are diagrams of masks used to create the hooks shown in FIGS. 12B and 13B respectively.

FIGS. 12B and 13B are diagrams showing the front view of a hook member formed using a mold formed from the masks shown in FIGS. 12A and 13A respectively.

FIGS. 14A-14C are diagrams of masks used to create cavities for hook molds.

FIGS. 15A, 15C, 15E, 16A, and 17A are diagrams of masks used to create hooks and stems shown in FIGS. 15B, 15D, 15F, 16B and 17B respectively.

FIGS. 15B, 15D and 15F are diagrams showing the front view of a hook member formed using a mold formed from the masks shown in FIGS. 15A, 15C and 15E respectively.

FIG. 16B is a diagram showing a perspective view of the stem created from the mask shown in FIG. 16A.

FIG. 17B is a diagram showing the top view of a stem created from the mask shown in FIG. 17A.

FIG. 18A is a diagram of the mask used to create the stem shown in FIGS. 18B- 18C.

FIGS. 18B and 18C are diagrams showing the side view and cross-sectional view, respectively, of a stem formed using the mask shown in FIG. 18A.

FIG. 18D is a diagram of a stem-like hook formed from the stem shown in FIGS. 18B-18C.

FIG. 19 is a diagram of a mask used to create cavities for hook molds that include loop diverters.

Like reference symbols in the various drawings indicate like elements.

### DETAILED DESCRIPTION

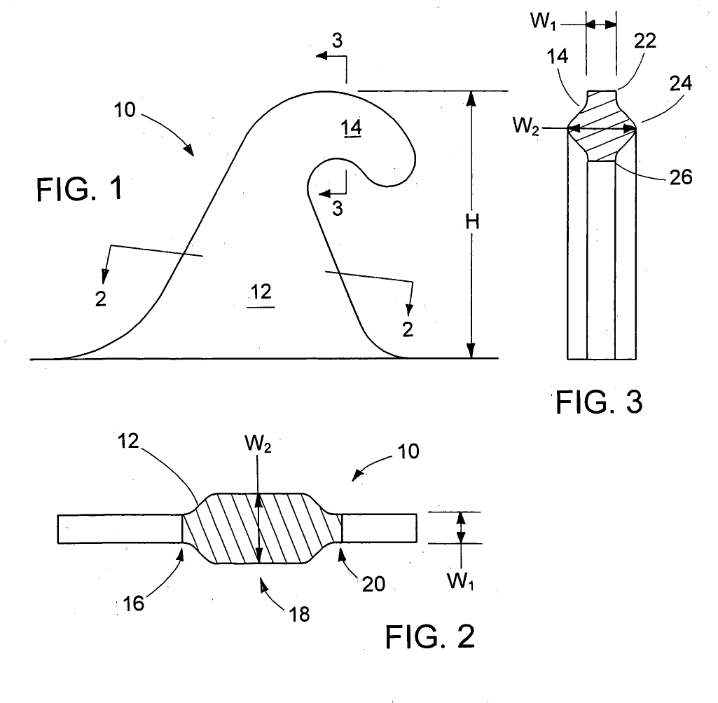

Referring to FIGS. 1-3, a mold cavity 10, which is used to form a hook on a hook component of a touch fastener, defines a pedestal portion 12 and a crook portion 14 and has a height H. The pedestal portion 12 of the mold cavity 10 has a cross-section that has a width W1 at one edge 16 of the cavity tapering out to width W2 in the center portion 18 and tapering back to width W1 at the other edge 20 of the cavity. Similarly, the crook portion 14 of the mold cavity has a cross-section that has width W1 at one edge 22 tapering out to width W2 in the center portion 24 and tapering back to width W1 at the other edge of the cavity 26. The thickened portion of the mold cavity, e.g., portions 18, 24, advantageously provides strength and resiliency to a hook formed from mold cavity 10.

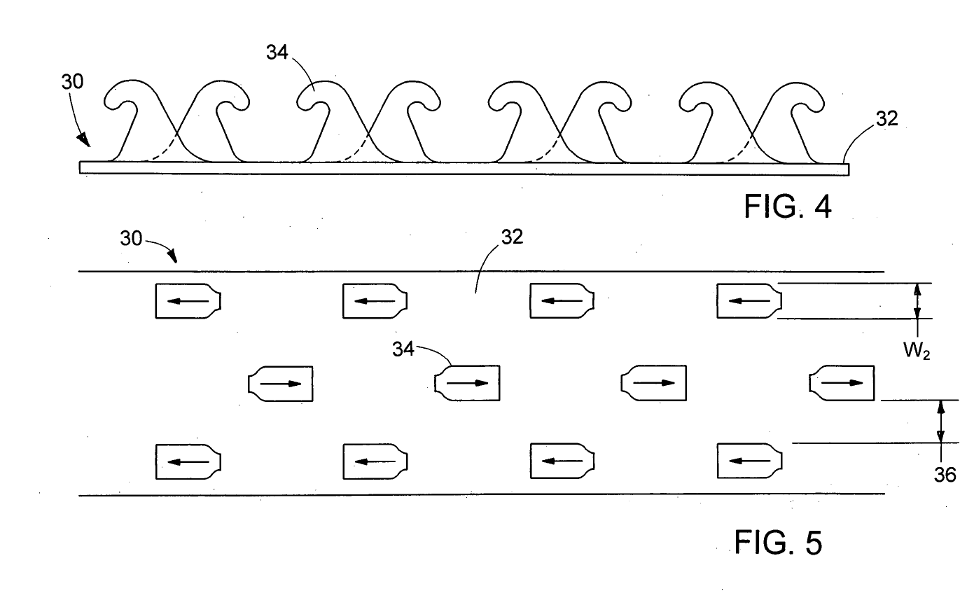

Referring to FIGS. 4 and 5, a hook component 30 of a touch fastener includes a sheet form base 32 and multiple parallel rows of integrally molded hook members 34. The molded hook members are formed from a mold cavity similar to the mold cavity shown in FIGS. 1 and 2, and, therefore, have a tapered cross-sectional widths ranging from W1 to W2. Ripstop bumps (not shown), i.e., known raised local regions of the base in spaces between rows of integrally molded hook members, may be employed either aligned with the hook members or offset from the hook members, depending upon the intended application.

In one implementation, there are approximately 24 hook members per lineal inch (9.44 hook members per lineal centimeter). The hook members are preferably spaced apart laterally (i.e., in the cross-machine direction) a distance 36 of about 0.008 inches (0.203 millimeters), and the pedestals 12 have a maximum thickness, W2, of about 0.006 inches (0.152 millimeters). This yields a density in the cross-machine direction of approximately 71 hook members per inch (27.95 members per linear centimeter). Hence, there are on the order of 1700 hook members per square inch (263.5 members per square centimeter) in this implementation.

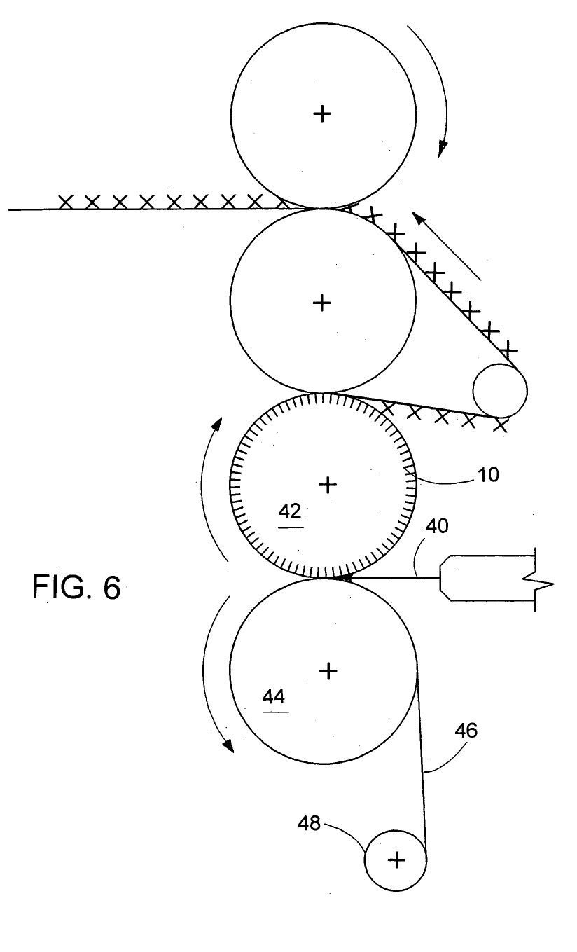

As shown in FIG. 6, a method for making such molded hook members entails extruding molten resin 40 into the nip formed between a cooled molding roll 42 and a pressure-applying roll 44. The cooled molding roll has mold cavities 10 about its periphery that are configured to produce hook members. A backing sheet 46, such as a woven or non-woven fabric, may be supplied from a backing sheet roll 48 to the nip. This backing sheet may contain loops adapted to engage the hook members. The resulting fastener element will then include hook members bound to the backing sheet in what may be termed an in situ laminating process. This process is described and illustrated in more detail in U.S. Pat. No. 5,900,350.

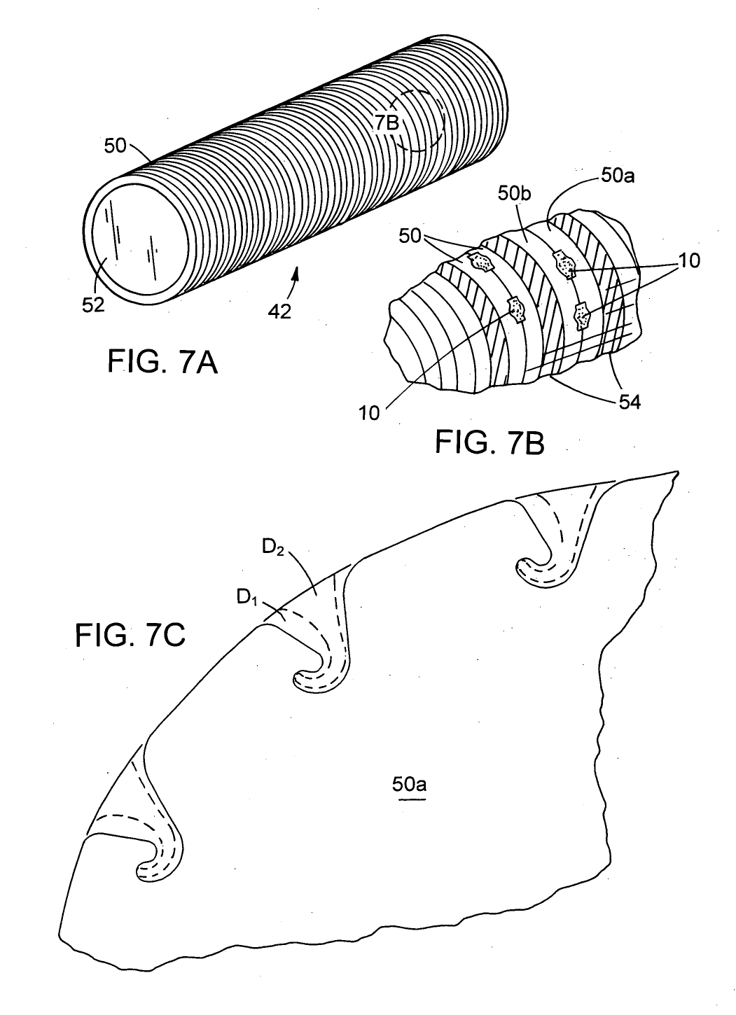

Referring to FIGS. 7A-7C, the molding roll 42 includes a series of tool rings 50 mounted on a cooled central barrel 52. The rings are pressed together axially to form a cylindrical surface. Mold cavities 10 are disposed along the periphery of a pair of adjacent tool rings, e.g., tool rings 50a, 50b. Spacer rings 54 are disposed between pairs of adjacent tool rings to provide the desired spacing between rows of mold cavities (e.g., dimension 36 shown in FIG. 5). The mold cavities, along with any bumps or other formations in the tool ring, are provided in a predetermined relationship to provide hook members on the base in a desired relationship, as the particular application requires. While in this implementation all of the mold cavities 10 formed by a mating pair of mold plates are identical, other implementations may use a variety of mold cavities formed by a mating pair of mold plates.

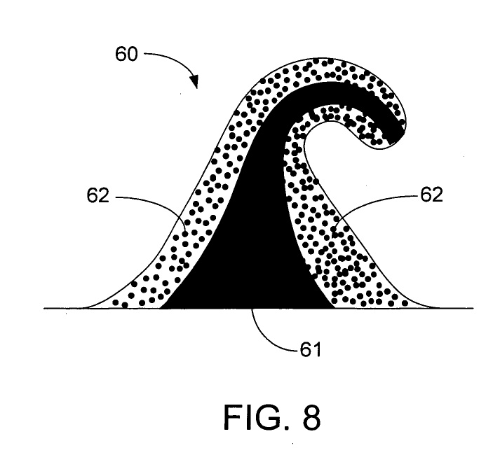

The mold cavities 10 are formed along the periphery of the tool rings by a chemical etch process. In one implementation, a tool ring formed of 17-7 PH stainless steel or other material susceptible to chemical etchant is coated with a layer of negative photoresist material. A mask, shown in FIG. 8, is placed over the photoresist and then exposed. Unexposed areas of the photoresist (i.e., the areas beneath the blacked-out portion of the mask) are removed using a solvent, e.g., an aqueous alkaline solution, which leaves the underlying substrate uncovered and ready for etching. The tool ring is then placed on a machine and sprayed with a strong acid, which removes exposed areas of the tool ring.

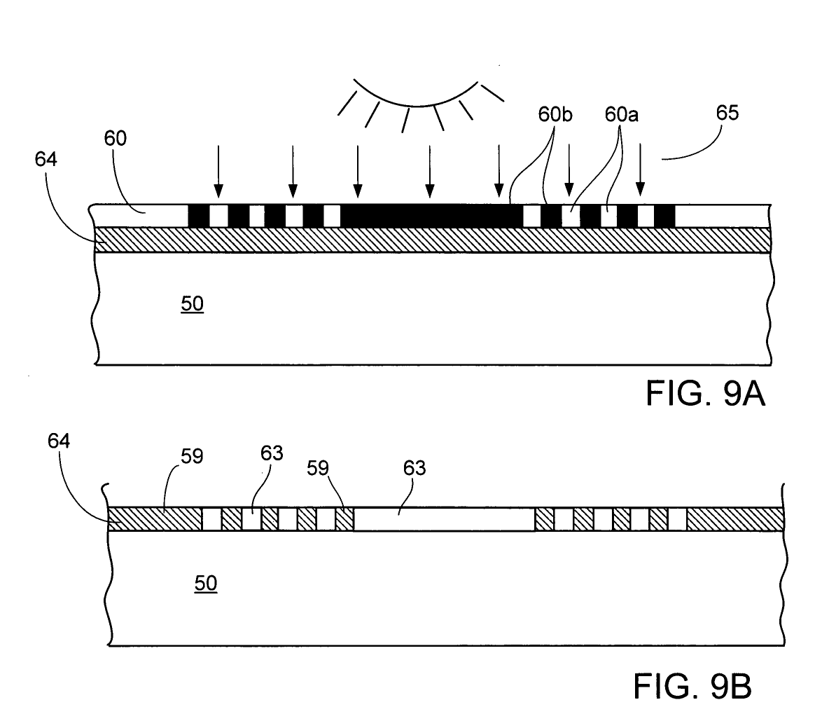

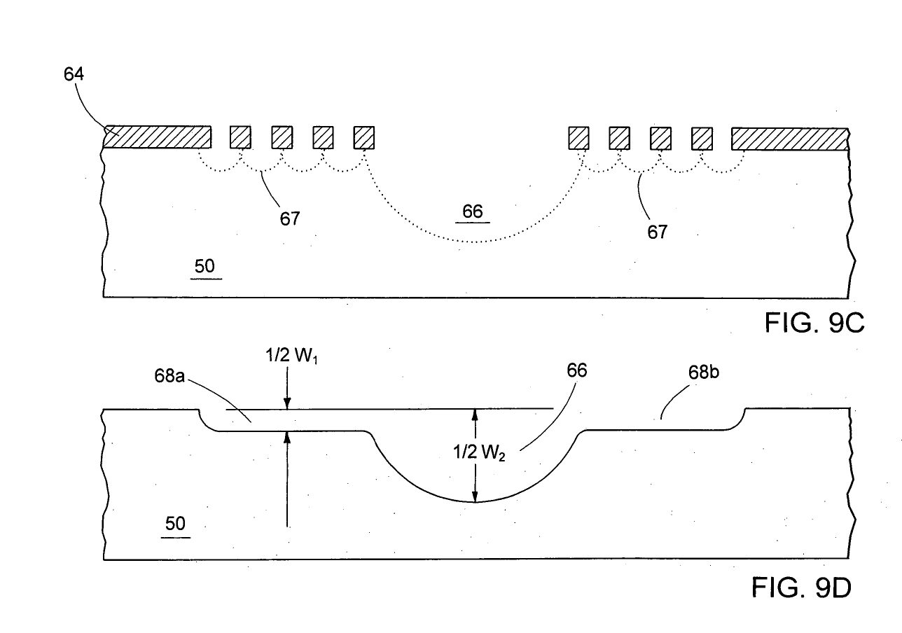

As shown in FIGS. 9A-9D, the depth of the etch is controlled by the exposure density of shaded area of the mask. In particular, when negative photoresist is employed, a deeper etch will result in areas beneath the mask that have a low exposure density (e.g., the completely blacked out area 61 of the mask 60) than in areas beneath the mask that have a higher exposure density (e.g., the shaded area 62 of the mask 60). Referring to FIG. 9A, an etchable tool ring 50 is coated with a negative photoresist material 64 and a patterned mask 60 is placed over the coated substrate. The photoresist material is exposed to light 65 causing the exposed areas to become cured and resistant to chemical etchant. Non-exposed areas of the photoresist (i.e., the areas beneath the blacked-out portions of the mask) are washed away and chemical etchant is sprayed on the tool ring. In areas where there is a relatively large gap between exposed areas of the plate, e.g., the completely blocked-out area 61 of mask 60 shown in FIG. 8, the etchant etches a relatively deep cavity 66 having a depth of ½ W2. In areas where the exposed areas of the plate are close together, e.g., the shaded area 62 of mask 60, the etchant etches a series of shallow cavities 67 that completely undercut adjacent areas of cured photoresist to form a single cavity 68a, 68b beneath the shaded areas of the mask having a depth of ½ W1.

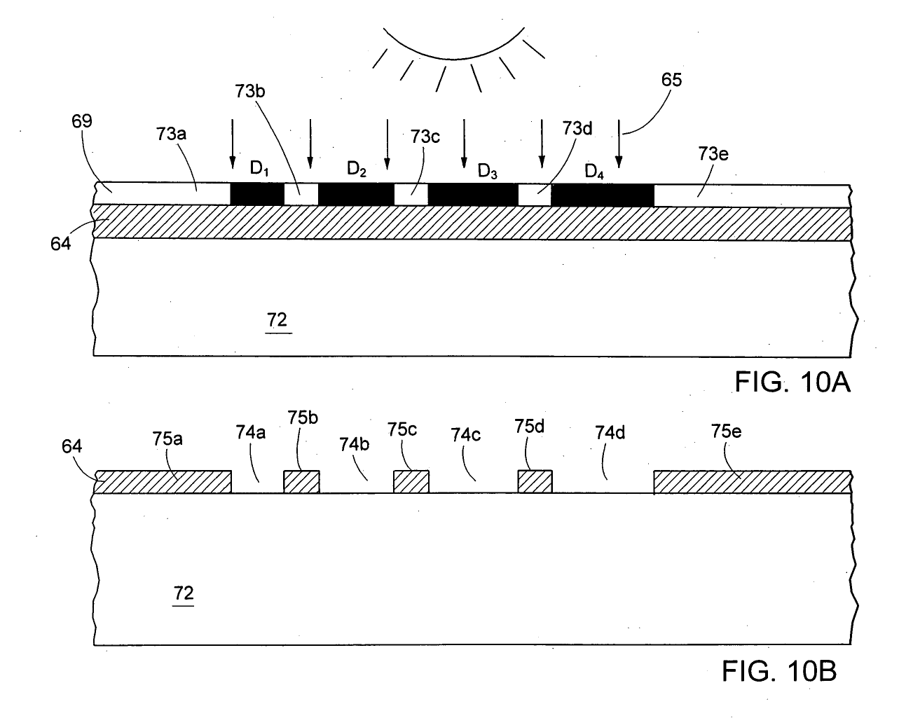

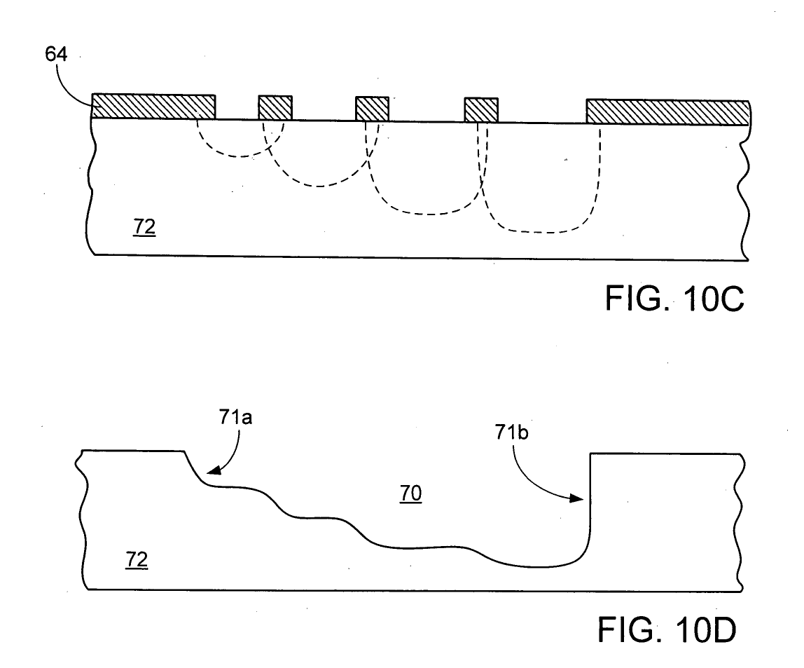

Similarly, as shown in FIGS. 10A-10D, a cavity 70 having a depth that gradually tapers from a relatively shallow depth at one end 71a to a relatively deeper depth at the other end 71b of the cavity is formed using a mask 69 having a series of light-blocking regions of increasing length. In particular, as shown in FIG. 10A, an etchable substrate 72 is coated with negative photoresist material 64 and a mask 69 is applied to the top of the photoresist material 64. The mask 69 has a pattern in which the distance between light-passing regions 73a-73e gradually increases from one end of the pattern to the other (i.e., D1<D2<D3<D4). The photoresist material is exposed to light 65 through the mask and the non-exposed areas (i.e., the areas beneath the light-blocking regions of the mask) are removed leaving a similar pattern of etchant-passing regions 74a-74d and etchant-blocking regions 75a-75e on the substrate. Chemical etchant is then applied to the prepared substrate to create a series of gradually deeper etches corresponding to the gradually increasing distance between etch-blocking regions. The etchant undercuts the interior etchant-blocking regions 75b-75d to create a contiguous cavity having a tapered depth.

In one implementation, the shaded mask, such as mask 60 shown in FIG. 8, is formed by plotting the mask pattern on a sheet of non-opaque material (e.g., glass plate or a plastic film such as Mylar® manufactured by E.I. du Pont de Nemours and Company headquartered in Wilmington, Del.) using a high-resolution plotter (e.g., 10,000 dpi). Other implementations may use other known techniques for creating photoresist masks, such as printing photoresist having the selected pattern directly on a substrate or printing masks using high-resolution printers. As shown in FIGS. 11A-11C, a mask may use a variety of patterns to control the depth of the etch, including dots, apertures, lines, crosshatch or combination thereof.

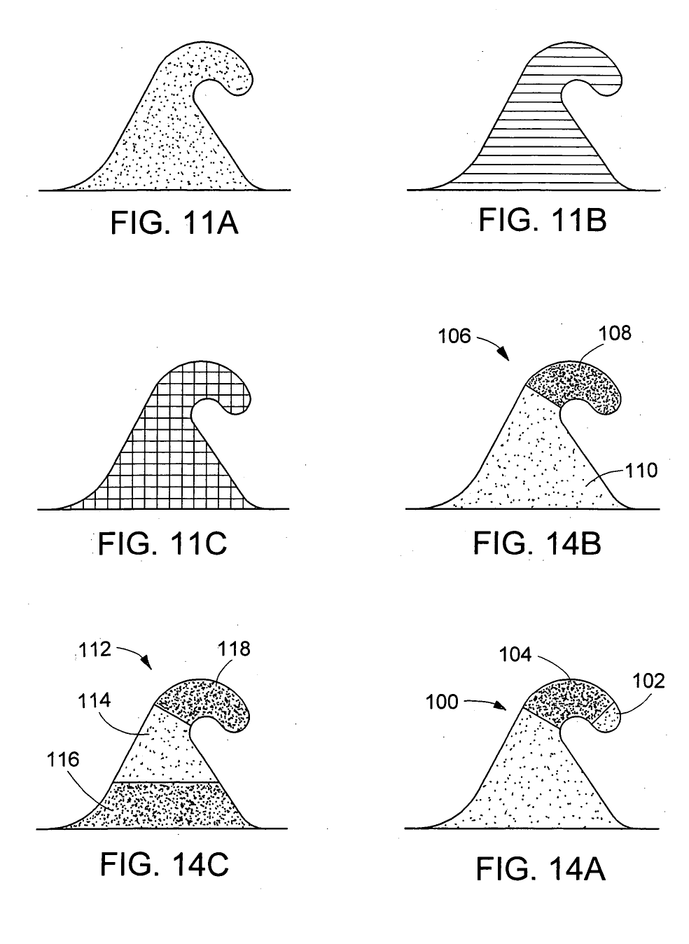

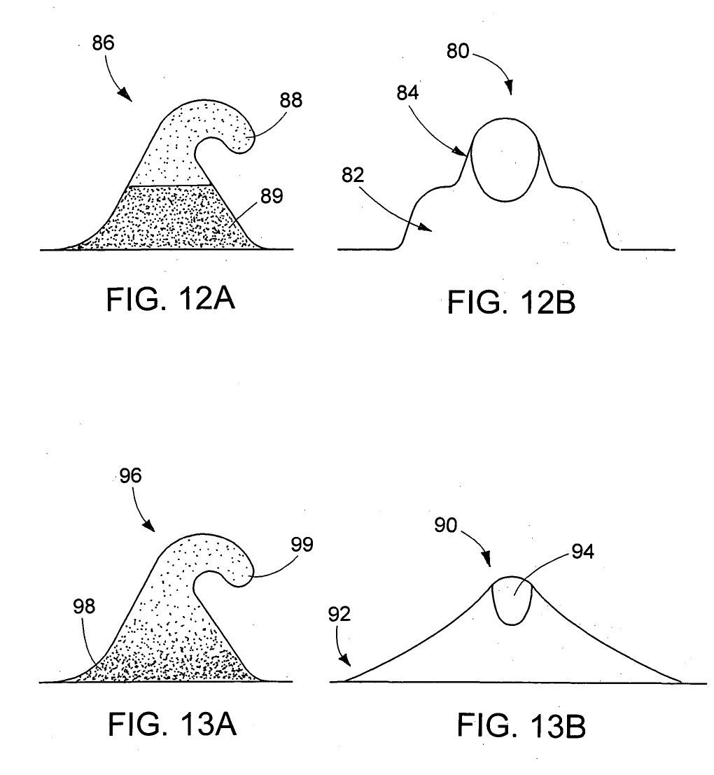

The use of a shaded photoresist mask in a photo-etching process provides a cost effective technique for creating hooks with a wide variety of shapes and features. For example, as shown in FIGS. 12A-12B, a hook 80 having a relatively wide pedestal portion 82 and a narrow crook portion 82 is formed using a mask 86 having a shaded crook portion and a completely blocked-out pedestal portion 89.

Similarly, as shown in FIGS. 13A-13B, a hook 90 that gradually tapers from a wide base 92 to a narrow crook 94 is formed using a mask 96 that is densely shaded at the base 98 and gradually becomes less densely shaded along the length of the mask. A tapered hook that comes to a relatively thin crook, such as that shown in FIG. 13B, is effective for grabbing loops. However, if the hook is too thin in the crook region, the hook is susceptible to deformation or breakage during use. A mask, such as mask 100 shown in FIG. 14A, may be used to maintain a tapered tip 102 for effective grabbing of hooks, while at the same time having a thickened portion 104 to add strength and resiliency to the crook region of the hook.

Because the crook portion of a hook is often substantially narrower than its base, a mold cavity etched with a uniformly shaded mask (e.g., a completely blacked-out mask) will often be shallower at the tip than at the base, thus creating a hook that is narrower at its tip than at its base. This etching difference can be compensated using a mask, such as mask 104 shown in FIG. 14B, that completely masks the tip 108 of the mold cavity and partially masks the base 110.

Referring to FIG. 14C, a hook may be formed that has a narrow central region by using a mask 112 that partially masks the central region 114 of the mold cavity and completely masks the base 116 and tip 118 of the mold cavity. This narrow central region can be beneficial for active and prolonged engagement with a loop.

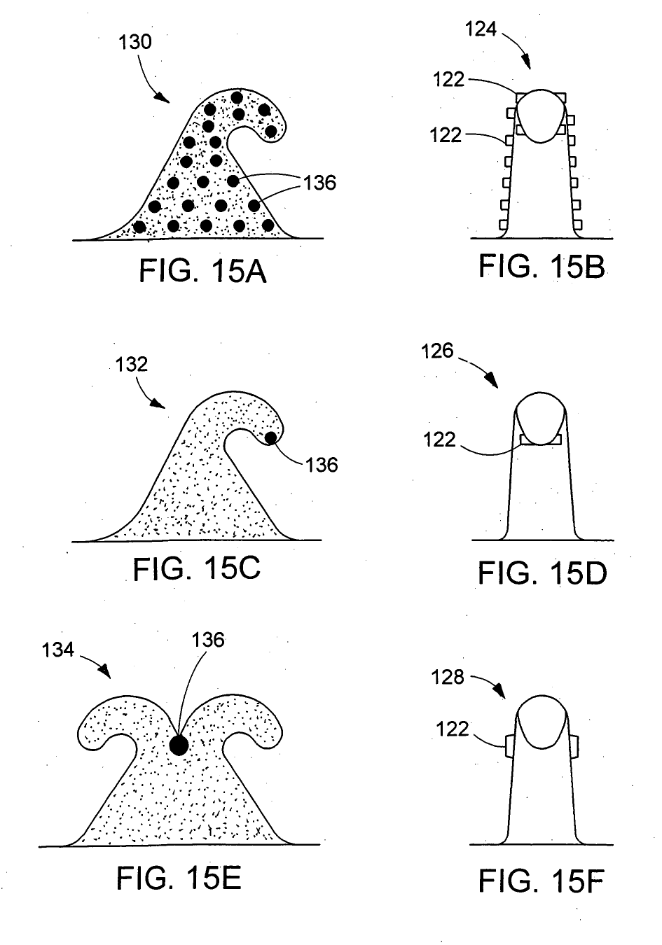

As shown in FIGS. 15A-15F, barbs 122 or other grabbing features are incorporated in hooks 124, 126, 128 using a mask 130, 132, 134 that has blocked-out or very densely shaded areas in locations 136 where a barb is desired. A barb located at or near the end of a hook, such as hook 126 shown in FIG. 15D, is also beneficial for prolonged engagement with a loop, and may result in an increase in the strength properties of the closure.

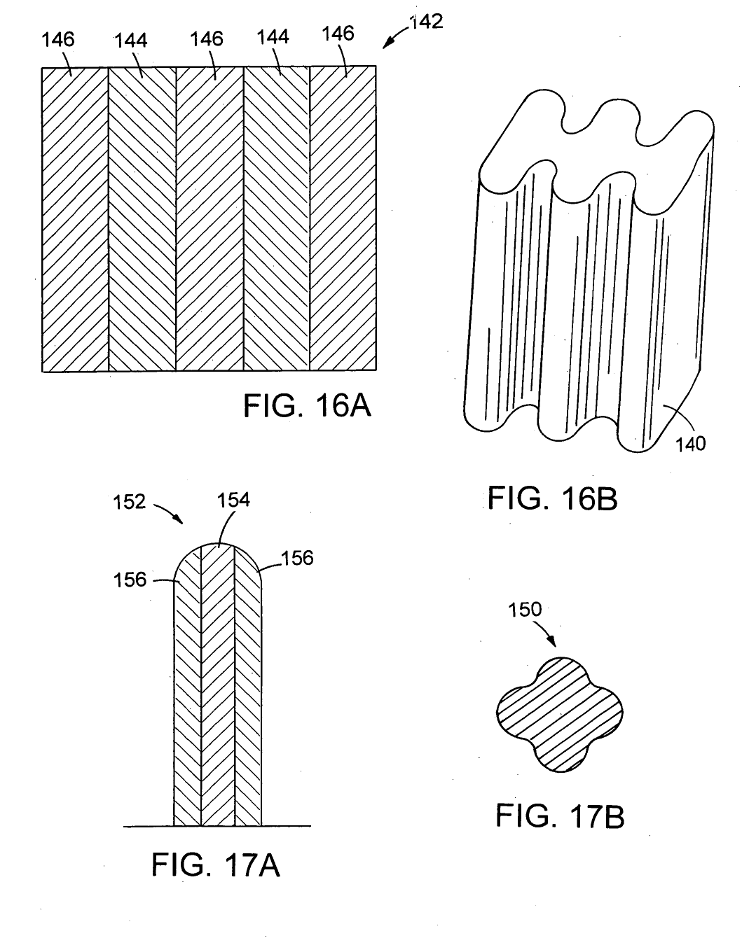

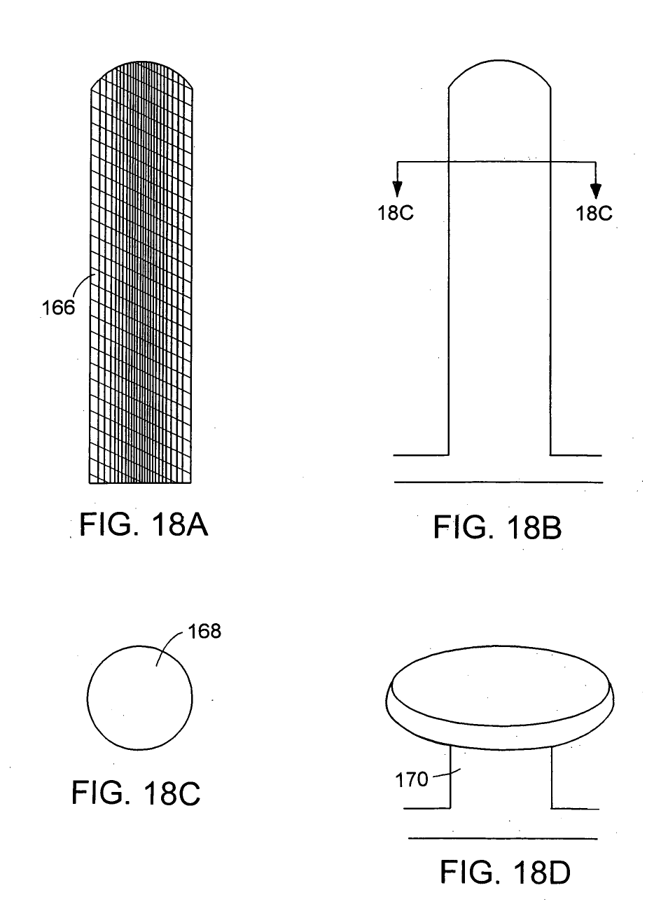

Shaded masks may be used to fabricate mold plates for a hook component of a touch fastener that employs stems and stem-like hooks described in U.S. application Ser. No. 10/455,240 filed Jun. 4, 2003, entitled “Hook and Loop Fastener” to Mark A. Clarner, George A. Provost, and William L. Huber, which is fully incorporated herein by reference. For example, as shown in FIGS. 16A-16B, a pronged stem-like hook 140 is formed using a mask 142 that has alternating bands of relatively densely-shaded areas 146 and relatively lightly-shaded areas 144. Similarly, as shown in FIGS. 17A-17B, a quadralobal stem 150 is formed using a mask 152 that has a relatively densely shaded band centered between two relatively lightly shaded bands 156. A mask with a densely-shaded area that gradually decreases in density towards the sides, such as mask 166, shown in FIG. 18A, could be used to create a cylindrical stem, 168, shown in FIGS. 18B-18C. Stem 168 could then be post-formed into a stem-like hook such as hook 170 shown in FIG. 18D.

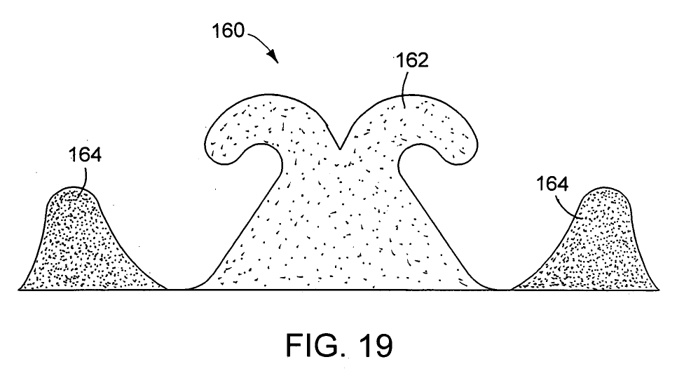

As shown in FIG. 19, a mask 160 includes a shaded region for a hook element 162 and two densely shaded regions 164 for a pair of hook diverter elements. Hook diverter elements are ridges or bumps are employed in some application to direct loops around hook elements. In this example, the hook diverter portion of the mask 164 is densely shaded to create a deeper etch, which results in a larger, more effective loop diverter.

A number of embodiments of the invention have been described. Nevertheless, it will be understood that various modifications may be made without departing from the spirit and scope of the invention. For example, in each of the above examples negative photoresist is used. While negative photoresist is currently preferred from a cost perspective, positive photoresist may also be used. When positive photoresist is used, areas that are exposed are weakened and become soluble and thus easily removed and the remaining portion of the photoresist (i.e., the area covered by a mask) remains on the plate. Therefore, masks adapted for use with positive photoresist will be the negative image of a mask adapted for use with negative photoresist.

As explained in detail in U.S. Pat. No. 5,900,350, hooks formed from mold rolls, such as roll 42 shown in FIG. 6, are often deformed during the molding process such that the resulting hook is not identical to the mold form. As a result, the mold cavities may be formed using a mask that compensates for the deformation that occurs during the molding process to produce a hook of the desired form. Other implementations may employ a mask having shaded regions to control the depth of the resulting mold cavity as described in this disclosure and also use the deformation compensation techniques described in U.S. Pat. No. 5,900,350.

Additionally, the mold cavities need not be formed on a tool ring adapted to produce hook fasteners by passing molten resin into a nip formed between a cooled molding roll and a pressure-applying roll as illustrated in FIG. 6, but may be formed on plates adapted to produce hook fasteners using other techniques. For example, a series of mold cavities may be formed on periphery of etchable plates having straight edges, which when assembled together to form a generally flat mold assembly having a series of mold cavities. Hook fasteners may then be produced by injecting or pouring molten resin onto the flat mold assembly or by stamping a sheet of molten resin with the flat mold assembly.

Moreover, the techniques described for fabricating a microhook mold cavity may be extended to a wide variety of other photochemical etching applications in which a cavity is etched on a substrate, such as forming a lens from a glass substrate, fabricating a tapered disk drive data head from a metallic substrate, or fabricating an integrated circuit from a semiconductor substrate.

Accordingly, other embodiments are within the scope of the following claims.

1. A method of forming a sheet-form product having an array of projections extending from a broad surface thereof, the method comprising:
forming a cavity on a first mold plate, including:
forming a layer of photoresist material on at least one side of the first mold plate, the layer of photoresist material comprising a pattern of etchant-passing and etchant-blocking regions; and
applying a chemical etchant to the plate such that the etchant undercuts the etchant-blocking regions to form a single contiguous cavity on the plate in an area beneath said pattern of etchant-passing and etchant-blocking regions;
assembling the first mold plate with one or more additional plates to form a mold, the cavity cooperating with a surface of an adjacent plate to at least partially define one of an array of mold cavities extending inward from a surface of the mold; and
applying resin to the surface of the mold and forcing some of the resin into the mold cavities to form an array of projections extending integrally from a layer of resin formed on the mold surface.

2. The method of claim 1 wherein forming a layer of photoresist material comprises:
applying photoresist material to at least one side of the first mold plate;
placing a mask over the photoresist material, the mask comprising a shaded region adapted to partially block exposure of photoresist material disposed beneath the shaded region; and
exposing the photoresist material to light through the mask.

3. The method of claim 1 wherein the etchant-passing regions comprise apertures bounded by said etchant-blocking regions.

4. The method of claim 1 wherein the etchant-blocking regions comprise discrete, bounded areas of photoresist material surrounded by etchant-passing regions void of photoresist material.

5. The method of claim 2 wherein the photoresist material comprises negative photoresist material and the exposure to light cures the photoresist material onto the plate, such that the photoresist material not exposed to the light is removed.

6. The method of claim 2 wherein the photoresist material comprises positive photoresist material and the exposure to light weakens the positive photoresist material such the photoresist material exposed to the light is removed.

7. The method of claim 1 wherein the pattern of etchant-passing and etchant-blocking regions is uniform.

8. The method of claim 7 wherein the cavity formed on the plate has an approximately uniform depth in the area beneath said pattern.

9. The method claim 1 wherein the pattern of etchant-passing and etchant-blocking regions is non-uniform.

10. The method of claim 9 wherein the cavity formed on the plate has a variable depth in the area beneath said pattern.

11. The method of claim 1 wherein the cavity has a hook shape.

12. The method of claim 1 wherein the cavity has a stem shape.

13. A method of forming a mold for forming a sheet-form product having an array of projections extending from a broad surface thereof, the method comprising:
applying a photoresist material to at least one side of a first mold plate;
placing a mask over the photoresist material, the mask comprising a shaded region adapted to partially block exposure of photoresist material disposed beneath the shaded region;
exposing the photoresist material to light through the mask; and
applying a chemical etchant to the plate such that a single contiguous cavity is formed on the plate in the area corresponding to the shaded region of the mask;
assembling the first mold plate with one or more additional plates to form a mold, the cavity cooperating with a surface of an adjacent plate to at least partially define one or an array of mold cavities extending inward from a surface of the mold.

14. The method of claim 13 wherein the photoresist material comprises negative photoresist material and the exposure to light cures the photoresist material onto the plate, such that the photoresist material not exposed to the light is removed.

15. The method of claim 13 wherein the photoresist material comprises positive photoresist material and the exposure to light degrades the positive photoresist material such the photoresist material exposed to the light is removed.

16. The method of claim 13 wherein the shaded region of the mask comprises a pattern of light-blocking regions and light-passing regions.

17. The method of claim 16 wherein the light-passing regions comprise apertures bounded by light-blocking regions.

18. The method of claim 16 wherein the light-blocking regions comprise discrete, bounded areas of mask material surrounded by light-passing regions void of mask material.

19. The method of claim 13 wherein the shaded region of the mask comprises a pattern of lines.

20. The method of claim 13 further comprising forming the mask using a plotter.

21. The method of claim 13 wherein the shaded region of the mask comprises an area having a uniform exposure density such that application of the chemical etchant to the plate results in a cavity having an approximately uniform depth in the area corresponding to the shaded region of the mask having a uniform exposure density.

22. The method of claim 13 wherein the shaded region of the mask comprises an area having a non-uniform exposure density such that application of the chemical etchant to the plate results in a cavity having a variable depth in the area corresponding to the shaded region of the mask having a non-uniform exposure density.

23. The method of claim 13 wherein the mask further comprises a second region adapted to completely block exposure of the photoresist material disposed beneath the second region.

24. The method of claim 13 wherein the cavity has a hook shape including a base and a tip and a cross-sectional area that tapers from the base of the cavity to the tip.

25. The method of claim 13 wherein the cavity has a hook shape that includes a pedestal portion and a crook portion which are contiguous and further including at least one barb protruding from either the pedestal portion or the crook portion.

26. The method of claim 13 wherein the first mold plate defines a perimeter, and the mold cavities are disposed along the perimeter of the plate.

27. The method of claim 13 wherein the etchable plate is ring-shaped.

28. A method of forming a cavity on a substrate the method comprising:
forming a layer of photoresist material on the substrate, the layer of photoresist material comprising a pattern of etchant-passing and etchant-blocking regions selected to form a single contiguous cavity in the substrate in the area beneath said pattern when a chemical etchant is applied; and
applying a chemical etchant to the substrate such that the etchant undercuts the etchant-blocking regions to form a single contiguous cavity on the plate in an area beneath said pattern of etchant-passing and etchant-blocking regions.

29. The method of claim 28 wherein forming a layer of photoresist material comprises:
applying photoresist material to the substrate;
placing a mask over the photoresist material, the mask comprising a shaded region adapted to partially block exposure of photoresist material disposed beneath the shaded region; and
exposing the photoresist material to light through the mask.

30. The method of claim 28 wherein the substrate is a mold plate adapted to be assembled with one or more additional plates to define a mold for a hook or- stem on a hook component of a touch fastener.

31. The method of claim 28 wherein the etchant-passing regions comprise apertures bounded by said etchant-blocking regions.

32. The method of claim 28 wherein the etchant-blocking regions comprise discrete, bounded areas of photoresist material surrounded by etchant-passing regions void of photoresist material.

33. The method of claim 29 wherein the photoresist material comprises negative photoresist material.

34. The method of claim 29 wherein the photoresist material comprises positive photoresist material.

35. The method of claim 28 wherein the pattern of etchant-passing and etchant-blocking regions is uniform.

36. The method of claim 35 wherein the cavity formed on the plate has an approximately uniform depth in the area beneath said pattern.

37. The method claim 28 wherein the pattern of etchant-passing and etchant-blocking regions is non-uniform.

38. The method of claim 37 wherein the cavity formed on the plate has a variable depth in the area beneath said pattern.

39. The method of claim 28 wherein at least a portion of the cavity penetrates through the substrate.
